(19) United States
(12) Patent Application Publication
(10) Pub. No.: US 2010/0202197 A1
(43) Pub. Date: Aug. 12, 2010

(54) OPERATION METHODS OF NONVOLATILE MEMORY DEVICE

(76) Inventor: Keon Soo SHIM, Gyeonggi-do (KR)

Correspondence Address: IP & T Law Firm PLC, 7700 Little River Turnpike, Suite 207, Annandale, VA, 22003, US

(21) Appl. No.: 12/651,038

(22) Filed: Dec. 31, 2009

(30) Foreign Application Priority Data
Feb. 10, 2009 (KR) 10-2009-0010599

(51) Int. Cl. G11C 16/04; G11C 16/06

(52) U.S. Cl. 365/185.03; 365/185.19; 365/185.22

(57) ABSTRACT

An operation method includes performing a first program operation and a first program verification operation on an even page memory cell group wherein the first program operation is performed such that the even page memory cell group is programmed to have a threshold voltage less than a target threshold voltage, performing a second program operation and a second program verification operation on an odd page memory cell group neighboring the even page memory cell group when the first verification operation is passed, performing a third program operation and a third program verification operation on the even page memory cell group when the second verification operation is passed, wherein the third program operation is performed such that the even page memory cell group is programmed to have a threshold voltage which is equal to or higher than the target threshold voltage.

### CROSS-REFERENCE TO RELATED APPLICATION

This application claims priority to Korean patent application number 10-2009-0010599 filed on Feb. 10, 2009, the entire disclosure of which is incorporated by reference herein

### BACKGROUND

One or more embodiments relate to program and read methods of a nonvolatile memory device and, more particularly, to program and read methods of a nonvolatile memory device, which are capable of preventing an interference effect and improving a read margin.

In a nonvolatile memory device, which is a type of a semiconductor memory device, a number of cells for storing data are coupled in series to each other to form a single string. A drain select transistor and a source select transistor are respectively formed between the cell string and the drain, and between the cell string and the source. The cell of the above NAND-type nonvolatile memory device includes a gate having a tunnel oxide layer, a floating gate, a dielectric layer, and a control gate stacked in a region of a semiconductor substrate and junctions formed on both sides of the gate.

Referring to FIG. 1A, a tunnel oxide layer 11 and a first polysilicon layer 12 are formed over a semiconductor substrate 10. Specific regions of the first polysilicon layer 12 and the tunnel oxide layer 11 are etched. The semiconductor substrate 10 is etched to a certain depth, thereby forming trenches. The trenches are filled with an insulating layer. A polishing process is performed to form isolation layers 13 in the respective trenches. Next, a second polysilicon layer 14 is formed on the entire surface, and is partially etched to form floating gates 12 and 14. A dielectric layer 15 and a polysilicon layer 16 for control gates are formed over the floating gates 12 and 14.

If, as described above, the nonvolatile memory device is manufactured using an SA-STI process, interference can occur between the first polysilicon layers 12 functioning as the floating gates because the isolation layer 13 is formed therebetween.

In such interference, the state of a specific cell is influenced by the operations of neighboring cells. In more detail, the state of a specific cell is changed by the operations (in particular, the program operations) of neighboring cells. The term ‘interference effect’ refers to a phenomenon in which, if a second cell neighboring a first cell to be read is programmed, the first cell is read as having a higher threshold voltage than its original threshold voltage because of a capacitance action resulting from a change in the charges of the floating gate of the programmed second cell. Although the amount of charges of the floating gate of a read cell is not changed, the state of the read cell is seen as being distorted because of a change in the state of a neighboring cell. Accordingly, the state of a cell is changed by such an interference effect, which results in an increased failure rate and a low yield.

FIG. 1B is a graph showing distributions of the threshold voltages of memory cells coupled to an even bit line (Even B/L) and an odd bit line (Odd B/L) when a program operation is performed on a known nonvolatile memory device.

From FIG. 1B, it can be seen that a distribution of the memory cells coupled to the even bit line and a distribution of the memory cells coupled to the odd bit line, from among the memory cells coupled to the nonvolatile memory device, differ from each other. In the program operation of a nonvolatile memory device, a threshold voltage distribution is formed to be greater than a set threshold voltage distribution through the program operation of the even bit line, and a threshold voltage distribution is then formed to be greater than a set threshold voltage distribution through the program operation of the odd bit line. Here, the threshold voltages of the memory cells coupled to the even bit line are raised because of the interference effect, thus having a threshold voltage distribution higher than that of the memory cells coupled to the odd bit line.

### BRIEF SUMMARY

One or more embodiments relate to program and read methods of a nonvolatile memory device, which are capable of reducing an interference effect by first programming a even page memory cell group of a nonvolatile memory device to have a threshold voltage less than a target threshold voltage, programming a odd page memory cell group of the nonvolatile memory device to have the target threshold voltage, and second programming the even page memory cell group to have the target threshold voltage, and which are capable of securing a read margin of a read operation by setting a pass voltage to be applied to unselected memory cells using a flag cell for storing information about a program operation during a read operation.

A program method according to an embodiment comprises performing a first program operation on a even page memory cell group, performing a first program verification operation on the even page memory cell group, performing a program operation and a program verification operation on an odd page memory cell group neighboring the even page memory cell group, performing a second program operation on the even page memory cell group, and performing a second program verification operation on the even page memory cell group.

The even page memory cell group is an even bit line group, and the odd page memory cell group is an odd bit line group.

The first verification operation is performed by applying a first pass voltage to memory cells neighboring a memory cell selected from the even page memory cell group and applying a second pass voltage to memory cells other than the selected memory cell and the neighboring memory cells, wherein the first pass voltage is lower than the second pass voltage.

The first program operation is performed such that the even page memory cell group is programmed to have a threshold voltage less than a target threshold voltage.

During the second program operation for the odd page memory cell group, a threshold voltage of the even page memory cell group rises because of an interference effect.

The second program operation is performed such that the even page memory cell group is programmed to have a threshold voltage which is equal to or higher than the target threshold voltage.

The program method further comprises, if, as a result of the first verification operation, the even page memory cell group has not been programmed, raising a program step voltage and performing the operations again from the first program operation.

The program method further comprises, if, as a result of the second program operation for the even page memory cell group, the even page memory cell group has not been programmed, raising a program step voltage and performing the operations again from the second program operation.

The program method further comprises, if, as a result of the second verification operation, the even page memory cell group has not been programmed, raising a program step voltage and performing the operations again from the second program operation.

The program method further comprises, after the program operation and the verification operation for the odd page memory cell group, storing program data of the odd page memory cell group in a flag cell.

According to an embodiment, there is provided a read method of a nonvolatile memory device including an even page memory cell group and an odd page memory cell group, comprising: reading determination data, indicating whether the odd page memory cell group has been programmed, from a flag cell, determining whether the odd page memory cell group has been programmed based on the read determination data, if, as a result of the determination, the odd page memory cell group is determined not to have been programmed, setting a pass voltage applied to memory cells neighboring a memory cell, selected from the even page memory cell group, as a first pass voltage which is lower than a second pass voltage applied to memory cells other than the selected memory cell and the neighboring memory cells, if, as a result of the determination, the odd page memory cell group is determined to have been programmed, setting the pass voltage applied to the neighboring memory cells as the second pass voltage which is applied to the memory cells other than the selected memory cell and the neighboring memory cells, and performing a read operation on the even page memory cell group by applying a read voltage to the selected memory cell and the set pass voltage to the neighboring memory cells.

A threshold voltage value of the even page memory cell group in the case where the odd page memory cell group has not been programmed may be less than a threshold voltage value of the even page memory cell group in the case where the odd page memory cell group has been programmed.

In the case where the read operation is performed in a state in which the first pass voltage is set as a pass voltage, a threshold voltage value of the selected memory cell is read as being higher than an actual threshold voltage value.

The even page memory cell group is an even bit line group, and the odd page memory cell group is an odd bit line group.

### BRIEF DESCRIPTION OF THE DRAWINGS

FIG. 1A shows the structure of a nonvolatile memory device;

FIG. 1B is a graph showing distributions of the threshold voltages of memory cells coupled to an even bit line and an odd bit line when a program operation is performed on a known nonvolatile memory device;

FIG. 2 shows the memory cell array of a nonvolatile memory device for illustrating program and read methods of a nonvolatile memory device according to an embodiment;

FIG. 3 is a flowchart illustrating a program method of a nonvolatile memory device according to one embodiment;

FIG. 4 is a graph illustrating threshold voltage values of memory cells which are sensed according to pass voltages applied to the memory cells in the direction of neighboring word lines of a nonvolatile memory device according to an embodiment;

FIG. 5 is a diagram showing distributions of the threshold voltages of memory cells of a nonvolatile memory device according to an embodiment;

FIG. 6 is a flowchart illustrating a program method of a nonvolatile memory device according to another embodiment; and

FIG. 7 is a flowchart illustrating a read method of a nonvolatile memory device according to an embodiment.

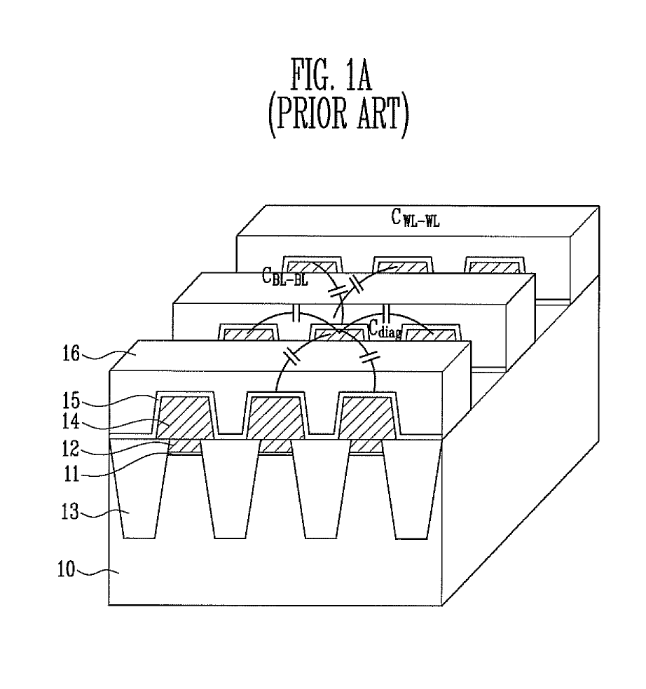

### DESCRIPTION OF EMBODIMENTS

Hereinafter, one or more embodiments of the present disclosure will be described in detail with reference to the accompanying drawings. The drawing figures are provided to allow those having ordinary skill in the art to understand the scope of the embodiments of the disclosure.

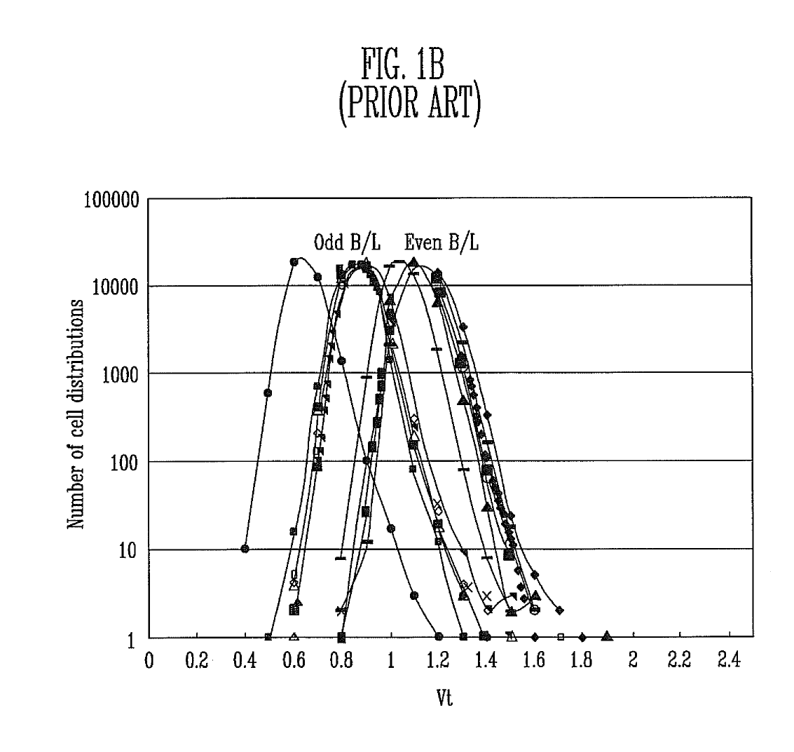

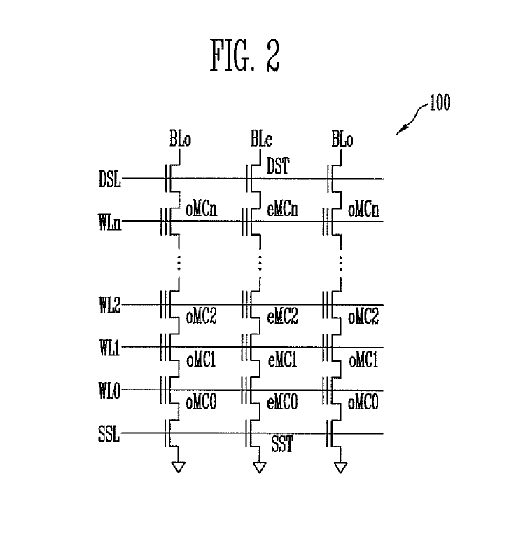

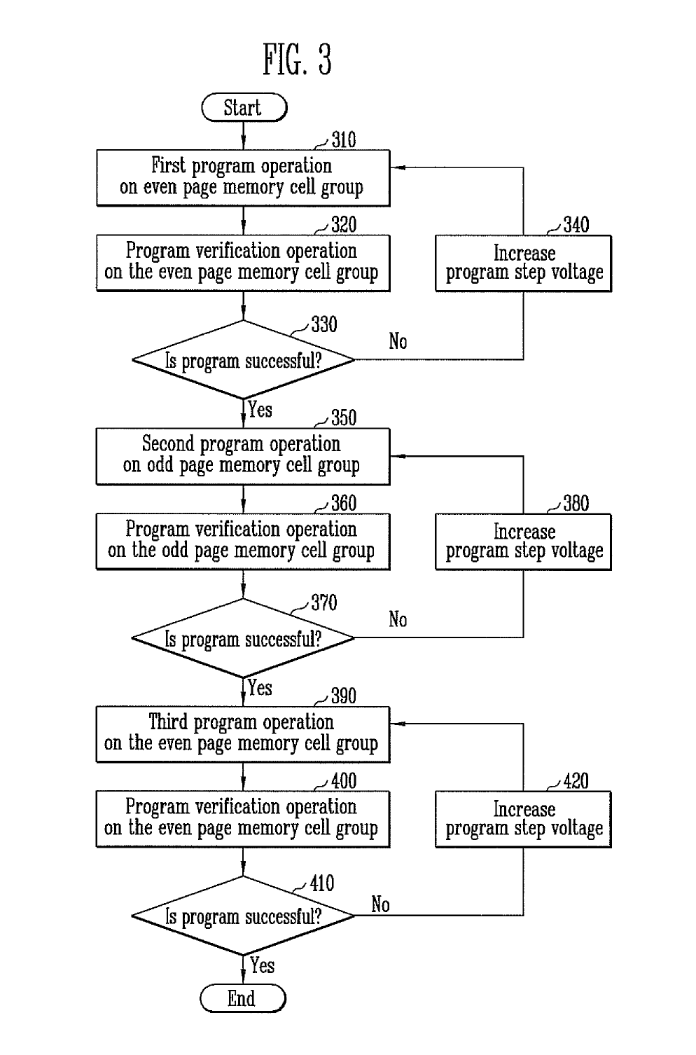

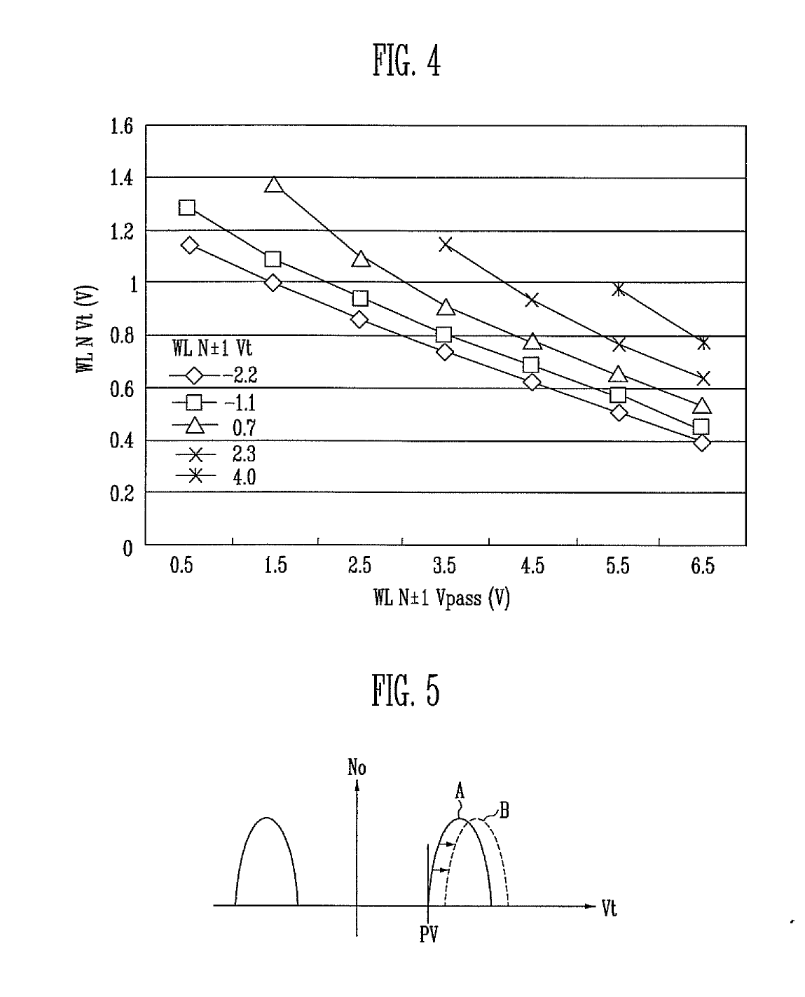

FIG. 2 shows a memory cell array 100 of a nonvolatile memory device for illustrating program and read methods of a nonvolatile memory device, according to an embodiment, FIG. 3 is a flowchart illustrating a program method of a nonvolatile memory device according to an embodiment, FIG. 4 is a graph illustrating threshold voltage values of memory cells which are sensed according to pass voltages applied to the memory cells in the direction of neighboring word lines of a nonvolatile memory device, according to an embodiment, and FIG. 5 is a diagram showing distributions of the threshold voltages of memory cells of a nonvolatile memory device, according to an embodiment.

Hereinafter, the program method of a nonvolatile memory device according to an embodiment is described with reference to FIGS. 2 to 5.

First, a first program operation is performed on a selected memory cell of an even page memory cell group at step 310. The even page memory cell group includes memory cells eMC0 to eMCn coupled to an even bit line BLe. A program operation is performed on a memory cell (e.g., eMC1) selected from among the memory cells eMC0 to eMCn. The program operation is performed by applying a program voltage to a word line WL1 coupled to the selected memory cell eMC1, e.g., as shown in FIG. 2. A program verification operation is performed on the even page memory cell group at step 320. During the verification operation, a second pass voltage lower than a first pass voltage which is applied to other memory cells (e.g., eMC3 to eMCn) is applied to the memory cells eMC0 and eMC2 which are adjacent to the selected memory cell eMC1 on the same bit line BLe. If, as described above, such a relatively low pass voltage is applied to the memory cells eMC0 and eMC2 neighboring the selected memory cell eMC1, the threshold voltage of the selected memory cell eMC1 is read as having been raised from A to B, as shown in FIG. 5. Accordingly, during the verification operation, the selected memory cell eMC1 is programmed to have a threshold voltage less than a target threshold voltage.

At step 330, it is determined whether the first program operation is successful as a result of the verification operation. If, as a result of the determination at step 330, the first program operation is unsuccessful (i.e., a threshold voltage of the even page memory cell group is determined to be lower than a verification voltage), the program voltage is raised at step 340, and the first program operation (310) and the program verification operation (320) are then performed again.

However, if, as a result of the determination at step 330, the first program operation for the even page memory cell group is determined to be successful, a second program operation is performed on an odd page memory cell group at step 350. The odd page memory cell group includes memory cells oMC0 to oMCn coupled to an odd bit line BLo. The program operation is performed on a memory cell (e.g., oMC1) selected from among the memory cells oMC0 to oMCn. The program operation is performed by applying a program voltage to the word line WL1 coupled to the selected memory cell oMC1. In this case, the threshold voltage of the memory cell eMC1 of the neighboring even page memory cell group may rise because of the interference effect.

Next, a program verification operation is performed on the odd page memory cell group at step 360. During the verification operation, a second pass voltage is applied to the memory cells oMC0 and oMC2 to oMCn, which are coupled to the same bit line BLo, except the selected memory cell oMC1.

At step 370, it is determined whether the program operation on the odd page memory cell group is successful as a result of the verification operation. If, as a result of the determination at step 370, the program operation on the odd page memory cell group is unsuccessful (i.e., a threshold voltage of the odd page memory cell group is determined to be lower than a verification voltage), the program voltage is raised at step 380, and the second program operation on the odd page memory cell group (350) and the program verification operation (360) are then performed again.

Next, at step 390, a third program operation is performed on the even page memory cell group. The second program operation is performed by applying a program voltage to the word line WL1 coupled to the selected memory cell eMC1 of the even page memory cell group. The applied program voltage preferably is higher than a program voltage that is used in the first program operation for the even page memory cell group.

A verification operation for the second program operation of the even page memory cell group is performed at step 400. During the verification operation, a second pass voltage applied to the memory cells eMC0 and eMC2 to eMCn which are coupled to the same bit line BLe as the selected memory cell eMC1 is applied. During the verification operation, it is determined whether each of the memory cells eMC0 and eMC2 to eMCn has been programmed to have a target threshold voltage value or more. If, as a result of the determination at step 410, any of threshold voltage values of the memory cells eMC0 and eMC2 to eMCn is less than the target threshold voltage value, the program voltage is raised at step 420, and the third program operation (390) and the verification operation (400) for the second program operation are performed again.

As described above, a first program operation (310) is performed on an even page memory cell group such that the even page memory cell group is programmed to have a threshold voltage value less than a target threshold voltage value. After the second program operation (350) is performed on an odd page memory cell group, a third program operation (390) is performed on the even page memory cell group such that the even page memory cell group is programmed to have a threshold voltage value higher than the target threshold voltage value. Accordingly, a shift in the threshold voltage resulting from an interference effect between cells during a program operation can be prevented.

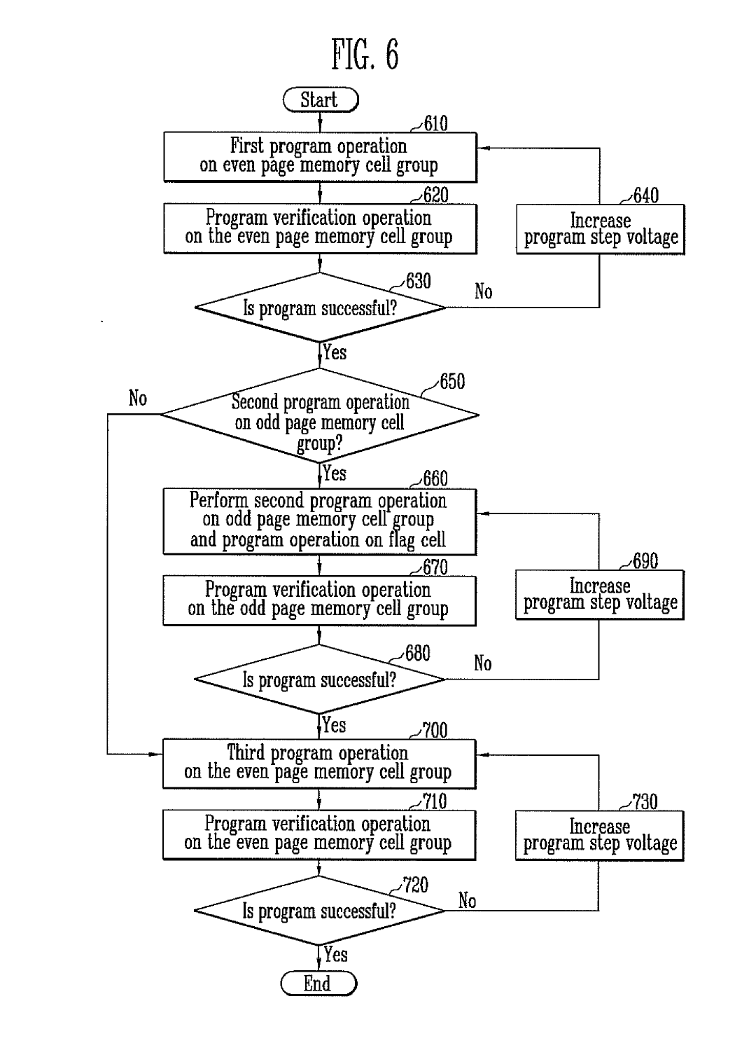

A program method of a nonvolatile memory device according to another embodiment is described with reference to FIG. 6.

A first program operation is first performed on a memory cell (e.g., eMC1) selected from an even page memory cell group at step 610. The even page memory cell group includes the memory cells eMC0 to eMCn coupled to the even bit line BLe. The program operation is performed by supplying a program step voltage to the word line WL1 coupled to the selected memory cell eMC1.

A program verification operation is performed on the even page memory cell group at step 620. During the program verification operation, a second pass voltage less than a first pass voltage, supplied to other memory cells (e.g., eMC3 to eMCn), is supplied to the memory cells eMC0 and eMC2 neighboring the selected memory cell eMC1 on the same bit line. This is because, when the second pass voltage less than the first pass voltage is supplied to the neighboring memory cells eMC0 and eMC2, the threshold voltage of the selected memory cell eMC1 is detected to have increased.

It is then determined whether the program verification operation is successful at step 630. If, as a result of the determination, the program verification operation is determined to be unsuccessful, the program step voltage is increased at step 640, and the process returns to the step 610.

If, as a result of the determination, the program verification operation is determined to be successful, it is determined whether a second program operation will be performed on an odd page memory cell group at step 650. If, as a result of the determination at step 650, the second program operation is determined not to be performed on the odd page memory cell group, a third program operation is performed on the selected memory cell eMC1 of the even page memory cell group at step 700.

However, if, as a result of the determination at step 650, the second program operation is determined to be performed on the odd page memory cell group, the second program operation is performed on a memory cell (e.g., oMC1) selected from the odd page memory cell group at step 660. The odd page memory cell group includes the memory cell oMC0 to oMCn coupled to the odd bit line BLo. The second program operation is performed by supplying a program step voltage to the word line WL1 coupled to the selected memory cell oMC1. At this time, the threshold voltage of the memory cell eMC1 of the even page memory cell group, neighboring the selected memory cell oMC1 of the odd page memory cell group, can be increased by an interference effect. During the second program operation for the odd page memory cell group, information about whether the second program operation has been performed on the odd page memory cell group is stored in a flag cell as determination data. In the case in which, after a program operation for an even page memory cell group, a program operation is not performed on an odd page memory cell group, there may be no shift in the threshold voltage of a memory cell resulting from an interference effect. Accordingly, such information is stored in a flag cell and used when a read operation is performed.

Next, a program verification operation is performed on the odd page memory cell group at step 670. During the program verification operation, the second pass voltage is supplied to the remaining memory cells oMC0, and oMC2 to oMCn coupled to the same bit line other than the selected memory cell oMC1.

It is then determined whether the program verification operation for the odd page memory cell group is successful at step 680. If, as a result of the determination, the program verification operation for the odd page memory cell group is determined to be unsuccessful, the program step voltage is increased at step 690, and the process returns to the step 660.

However, if, as a result of the determination at step 680, the program verification operation is determined to be successful, a third program operation is performed on the selected memory cell eMC1 of the even page memory cell group at step 700. The third program operation is performed by supplying a program step voltage to the word line WL1 coupled to the selected memory cell eMC1. The program step voltage preferably is higher than the program step voltage used when the first program operation for the even page memory cell group is performed.

Next, a program verification operation is performed on the even page memory cell group at step 710. During the program verification operation, the second pass voltage is supplied to the remaining memory cells eMC0, and eMC2 to eMCn coupled to the selected memory cell eMC1 on the same bit line.

It is then determined whether the program verification operation for the even page memory cell group is successful at step 720. If, as a result of the determination, the program verification operation is determined to be unsuccessful, the program step voltage is increased at 730, and the process returns to the step 700.

As described above, a first program operation is performed on an even page memory cell group such that a selected memory cell of the even page memory cell group has a threshold voltage less than a target threshold voltage. After the first program operation, a third program operation is performed on the even page memory cell group such that the selected memory cell of the even page memory cell group has a threshold voltage higher than the target threshold voltage. Accordingly, a shift in the threshold voltage of a memory cell, occurring resulting from an inter-cell interference effect during a program operation, can be suppressed.

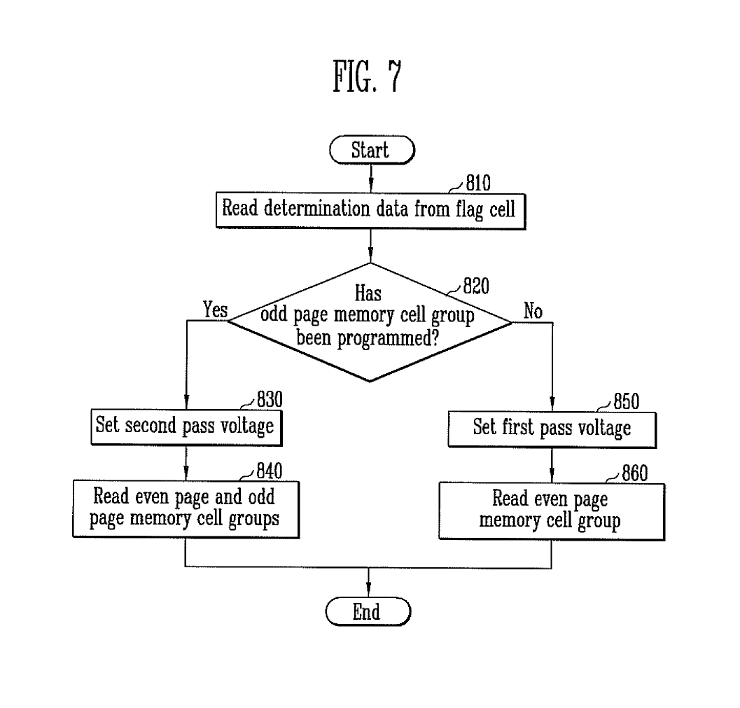

FIG. 7 is a flowchart illustrating a read method of a nonvolatile memory device according to an embodiment.

The read method of a nonvolatile memory device according to an embodiment is described below with reference to FIGS. 4, 5, and 7.

Determination data, indicating whether a program operation for the odd page memory cell group is programming, is read from the flag cell at step (810).

At step 820, it is determined whether a program operation for the odd page memory cell group is successful based on the read determination data. During the read operation, a pass voltage applied to the memory cells eMC0 and eMC2 neighboring a selected memory cell (e.g., eMC1) is set.

If, as a result of the determination at step 820, the program operation for the odd page memory cell group is determined to be successful, a second pass voltage applied to the memory cells eMC3 to eMCn is set as a pass voltage applied to the neighboring memory cells eMC0 and eMC2 at step 830. However, if, as a result of the determination at step 820, the program operation for the odd page memory cell group is determined to be unsuccessful and only a program operation for the even page memory cell group is successful, a first pass voltage lower than the second pass voltage applied to the memory cells eMC3 to eMCn is set as a pass voltage applied to the neighboring memory cells eMC0 and eMC2 at step 850.

If, as a result of the determination at step 820, the program operation for the odd page memory cell group is determined to have been performed, the second pass voltage is set at step 830, and a read operation is performed on the even page memory cell group and the odd page memory cell group at step 840.

If, as a result of the determination at step 820, the program operation for the odd page memory cell group is determined not to have been performed, the first pass voltage is set at step 850, and a read operation is performed on the even page memory cell group at step 860.

In the case where a program operation has been performed on the odd page memory cell group, the selected memory cell eMC1 of the even page memory cell group has a threshold voltage distribution, such as that shown in B of FIG. 5, because of an interference effect. Accordingly, in order to read the selected memory cell eMC1, a general second pass voltage is applied to the neighboring memory cells eMC0 and eMC2 such that the threshold voltage of the selected memory cell eMC1 rises. However, in the case where a program operation has been performed on the even page memory cell group, the selected memory cell eMC1 of the even page memory cell group can have a threshold voltage distribution lower than a threshold voltage distribution, such as that shown in B of FIG. 5, because it is not influenced by an interference effect. Accordingly, in order to increase the read margin of a read operation, a first pass voltage lower than a general second pass voltage is applied to the neighboring memory cells eMC0 and eMC2 such that the threshold voltage of the selected memory cell eMC1 rises.

According to the embodiments of the present disclosure, the even page memory cell group of a nonvolatile memory device is first programmed to have a voltage lower than a target threshold voltage. The odd page memory cell group of the nonvolatile memory device is programmed to have the target threshold voltage. The even page memory cell group is second programmed to have the target threshold voltage. Accordingly, an interference effect can be reduced or prevented. Furthermore, a pass voltage to be applied to unselected memory cells is set using a flag cell storing information about a program operation during a read operation. Accordingly, a read margin of a read operation can be secured.

What is claimed is:

1. An operation method of a nonvolatile memory device, comprising:
performing a first program operation and a first verification operation on an even page memory cell group, wherein the first program operation is performed such that the even page memory cell group is programmed to have a threshold voltage less than a target threshold voltage;
performing a second program operation and a second verification operation on an odd page memory cell group neighboring the even page memory cell group when the first verification operation is passed; and
performing a third program operation and a third verification operation on the even page memory cell group when the second verification operation is passed, wherein the third program operation is performed such that the even page memory cell group is programmed to have a threshold voltage which is equal to or higher than the target threshold voltage.

2. The operation method of claim 1, wherein:
the even page memory cell group is an even bit line group, and
the odd page memory cell group is an odd bit line group.

3. The operation method of claim 1, wherein the first verification operation is performed by applying a first pass voltage to neighboring memory cells adjacent to the selected memory cell of the even page memory cell group and applying a second pass voltage to memory cells other than the selected memory cell and the neighboring memory cells, wherein the first pass voltage is lower than the second pass voltage.

4. The operation method of claim 1, further comprising;
increasing a first program step voltage and performing the first program operation and the first verification operation again, when the first verification operation is failed.

5. The operation method of claim 1, further comprising;
increasing a second program step voltage and performing the second program operation and the second verification operation again, when the second verification operation is failed.

6. The operation method of claim 1, further comprising;
increasing a third program step voltage and performing the third program operation and the third verification operation again, when the third verification operation is failed.

7. The operation method of claim 1, wherein a threshold voltage of the even page memory cell group rises because of an interference effect during the second program operation for the odd page memory cell group.

8. The operation method of claim 1, further comprising;
storing a program data of the odd page memory cell group in a flag cell during the performing the second program operation.

9. An operation method of a nonvolatile memory device including an even page memory cell group and an odd page memory cell group, the read method comprising:
reading determination data, indicating whether the odd page memory cell group has been programmed, from a flag cell;
determining whether the odd page memory cell group has been programmed based on the read determination data;
and
setting a second pass voltage supplied to memory cells other than the selected memory cell and the neighboring memory cells of the even page memory cell group and performing the read operation of the even and the odd page memory cell group when the odd page memory cell group has been programmed.

10. the operation method of claim 9, setting a first pass voltage supplied to memory cells neighboring a selected memory cell of the even page memory cell group and performing a read operation of the even page memory cell group when the odd page memory cell group has not been programmed,
wherein the first pass voltage is higher than the second pass voltage.

11. The operation method of claim 10, wherein a threshold voltage of the even page memory cell group, where the odd page memory cell group has not been programmed, is less than that of the even page memory cell group, where the odd page memory cell group has been programmed.

12. The operation method of claim 10, wherein the performing the read operation when the odd page memory cell group has not been programmed, a threshold voltage of the selected memory cell is read as being higher than an actual threshold voltage.

13. The operation method of claim 9, wherein:
the even page memory cell group is an even bit line group, and
the odd page memory cell group is an odd bit line group.

14. An operation method of a nonvolatile memory device, comprising:
programming first memory cells coupled to even bit lines of a selected page such that each of the memory cells has a threshold voltage higher than a first level;
programming second memory cells coupled to odd bit lines of the selected page such that each of the memory cells has a threshold voltage higher than a second level; and
re-programming the first memory cells coupled to the even bit lines such that each of the memory cells has a threshold voltage higher than the second level.

15. The operation method of claim 14, wherein the programming of first memory cells coupled to even bit lines comprises:
applying a program voltage to a selected memory cell of the first memory cells; and
performing a first verification operation on the first memory cells by applying a first verification voltage to the memory cells other than the selected memory cell.

16. The operation method of claim 15, wherein the programming of second memory cells coupled to odd bit lines comprises:
applying a program voltage to a selected memory cell of the second memory cells; and
performing a second verification operation on the second memory cells by applying a second verification voltage to the memory cells other than the selected memory cell,
wherein the first verification voltage is lower than the second verification voltage.

17. The operation method of claim 16, wherein the re-programming of the first memory cells coupled to the even bit lines such that each of the memory cells has a threshold voltage higher than the second level comprises:
applying the program voltage to a selected memory cell of the first memory cells; and
performing a third verification operation on the first memory cells by applying the second verification voltage to the memory cells other than the selected memory cell.

18. The operation method of claim 14, wherein the first level is lower than the second level.

19. The operation method of claim 14, wherein a threshold voltage of each of the memory cells coupled to the even bit lines rises because of an interference effect during the programming of memory cells coupled to odd bit lines of the selected page.
